(19) United States
(12) Patent Application Publication
(10) Pub. No.: US 2024/0304768 A1
(43) Pub. Date: Sep. 12, 2024

(54) LIGHT EMITTING DEVICE COMPRISING A COOLING SYSTEM

(71) Applicants: CENTRE NATIONAL DE LA RECHERCHE SCIENTIFIQUE, PARIS (FR); UNIVERSITE PARIS-SACLAY, GIF-SUR-YVETTE (FR); INSTITUT D'OPTIQUE THEORIQUE ET APPLIQUEE, PALAISEAU CEDEX (FR)

(72) Inventors: François BALEMBOIS, BOISSY LE SEC (FR); Pierre PICHON, PALAISEAU (FR)

(73) Assignees: CENTRE NATIONAL DE LA RECHERCHE SCIENTIFIQUE, PARIS (FR); UNIVERSITE PARIS-SACLAY, GIF-SUR-YVETTE (FR); INSTITUT D'OPTIQUE THEORIQUE ET APPLIQUEE, PALAISEAU CEDEX (FR)

(21) Appl. No.: 18/573,817

(22) PCT Filed: Jun. 22, 2022
(86) PCT No.: PCT/EP2022/066959

§ 371 Date: Dec. 22, 2023

(30) Foreign Application Priority Data
Jun. 25, 2021 (EP) 21305883.7

(51) Int. Cl. H01L 33/58; H01L 25/075; H01L 33/64

(52) U.S. Cl. CPC H01L 33/58; H01L 25/0753; H01L 33/644

(57) ABSTRACT

A light emitting device including a plurality of light emitting diodes (LED) configured to emit an incident light; a solid luminescent concentrator (CL) of index n_{c} including two parallel faces, called large faces (FE1, FE2), along an horizontal plane xy, and n∈ [symbol] >2 faces called side faces (FL1, FL2, FL3, F4), at least one of the first and the second large face being illuminated by the incident light (Ld), the concentrator being configured to absorb the incident light (Ld) and then emit a luminescent light (L_{L}), a portion of the luminescent light being guided by total internal reflection (Lg) in the concentrator and passing through a first so-called exit face of the concentrator (FL1) in contact with an exit medium (EM) of index nₛ<n_{c}, and forming an exit beam; a cooling system (CS) including a cooling medium (CM) in contact with at least one of the faces of the concentrator.

### TECHNICAL FIELD

The present invention concerns the field of luminescent light concentrator, and more particularly to concentrator comprising a cooling system.

### PRIOR ART

Light-emitting diodes (LEDs) have many applications in the field of lighting. However, the luminance of LEDs is limited to values that are not suitable for some applications.

One solution to increase the luminance of LEDs is to use LED-pumped luminescent concentrators (see for example Barbet, Adrien, et al. “Light-emitting diode pumped luminescent concentrators: a new opportunity for low-cost solid-state lasers.” Optica 3.5 (2016): 465-468). This concentrator is, for example, a crystal that emit fluorescent light in the visible (red-orange) range, such as Ce:YAG, which absorbs in the blue range (around 450 nm), at a wavelength where LEDs are very efficient. The crystal is cut in the form of a plane, lined by hundreds (even thousands) of LEDs on both large surfaces and with an emission by the edges. These concentrators can achieve luminance values 10 to 20 times higher than that of an LED.

FIG. 1A illustrates an example of a light emitting module ME0 known in the prior art based on a concentrator crystal CL. FIG. 1A schematically represents a perspective view of the emission module ME0. The emission module ME0 comprises a set of LEDs emitting in a first spectral band, and a light concentrator CL. The concentrator CL is a fluorescent parallelepiped crystal, having at least one illumination face SI1, SI2, of dimensions L×w, illuminated by the electroluminescent radiation Ld emitted by the LEDs. The illumination faces SI1, SI2 are also called “large faces”. The other 4 faces are called lateral faces.

The crystal of the concentrator is configured to absorb the electroluminescent radiation Ld. The luminous flux emitted by the LEDs and directed towards the illumination face is absorbed by the luminophores Lum of the fluorescent crystal which are distributed throughout the volume of the crystal and which then emit fluorescence radiation inside the crystal. The emitted rays of the fluorescence radiation can be classified in two main categories:
trapped rays noted Lp: these rays are trapped in the crystal due to the total internal reflection (TIR) on the different faces of the crystal. These rays exist if the crystal is a parallelepiped with 6 faces parallel two by two. The trapped rays never leave the crystal;
the untrapped rays are the rays that eventually leave the crystal. They can be separated into two sub-categories: guided rays Lg, which are guided by TIR on the faces of the concentrator and then emerge on one of the faces of the concentrator, and unguided rays Lₒᵤₜ, which emerge directly from the concentrator without being reflected on the faces. The rays that pass through the side face SE forms the exit beam Lₛ.

FIG. 1B is a planar representation of the escape cones L_{g}, and Lₒᵤₜ using angular coordinates (α, β) in the xyz frame of reference: β is the angle with respect to the Oz axis. α is the angle in the xy plane, with respect to the Ox axis. The lighter area in between the cones corresponds to the trapped rays Lp. This representation is given as an example, with respect to the prior art crystal of FIG. 1A, with a diamond crystal (refractive index n=2.4). For diamond, given the Snell-Descartes law, the critical angle is θ_{c}=24,6° assuming the ambient medium is air. From FIG. 1B, one can see the 4 escape cones corresponding to the angles of the rays L_{g} guided by TIR and escaping through the 4 side faces. The escape cone corresponding to the ray forming the exit beam Lₛ is the second one to the left. The percentage of radiation trapped by TIR compared to the untrapped radiation is fixed by the index of the crystal and that of the ambient medium, by the Snell-Descartes law. For a parallelepiped concentrator made out of diamond (n=2.4) in ambient air, the percentage of trapped ray is 73%.

In concentrator crystals, the power of the exit beam can be increased via the increase of the pump power. However the pump power is limited by the difficulty to cool a concentrator. The total internal reflection (TIR) on the guiding faces is very sensitive to contact with materials of higher index than air. TIR can be very easily frustrated, inducing light leakage from faces other than the exit face thus reducing the light extraction efficiency of the exit beam Lₛ. The first strategy to limit this problem is to operate the pump LED in quasi-continuous wave: the peak power can be increased whereas the average pump power is maintained at a low level compatible with passive cooling of the concentrator (A. BARBET, et al. “LED pumped luminescent concentrators: a new opportunity for low cost solid-state lasers” Optica, Vol. 3, N°5, pp. 465-468 (April 2016).

For high average pump power in quasi-continuous operation or for continuous wave operation, the simplest solution, is to cool the concentrator with air (D. K. G. de Boer, et al. High-brightness source based on luminescent concentration. Optics Express, vol. 24, no. 14, page A169 July 2016). In Sathian, J. et al. “Solid-state source of intense yellow light based on a Ce:YAG luminescent concentrator.” Optics Express, vol. 25, no. 12, page 13714, June 2017, the concentrator is cooled using two copper blocks while avoiding optical contact with the concentrator. In Christoph Hoelen, et al. “Progress in extremely high brightness LED-based light sources” Sixteenth International Conference on Solid State Lighting and LED-based Illumination Systems, Proc. of SPIE Vol. 10378, 103780N, the concentrator is cooled by a mechanical contact in the form of tips on the two largest lateral faces of the concentrator. As the side faces are less stressed by the total internal reflection, it is consistent that the contact induced losses (losses announced at 1-2%) are quite low. It should be noted, however, that the pump power used in this setup remains moderate, and the cooling capacity of the setup is low. Likewise, CA 2929118 features cooling by mechanical parts positioned near the concentrator (“within 30 μm” on the hub, “within 10 μm but more than 1 μm” on the output guide).

However, all these methods are quite inefficient to remove the heat in the crystal and are not adapted to a high input power (eg pumping the crystal with thousands of LED each emitting at the watt level).

To avoid the frustration of the total internal reflection, one solution is to place a mirror on the guide faces of the concentrator. Contact cooling is then possible behind the reflecting surface, without changing the reflectivity of the surface. For example, Juna Sathian, et al. “Enhancing Performance of Ce:YAG Luminescent Concentrators for High Power Applications” CLEO Europe 2019 paper CD′-P.2 (2019)) use this type of cooling on a large face of a Ce:YAG concentrator covered with a dielectric mirror, in contact with a copper radiator. The reflectivity obtained by this treatment is less efficient than the total internal reflection: in the case of an exit face in the air, the induced losses are moderate (6%). This method allows to limit the heating of the Ce:YAG to a temperature difference of 10° for a pump power of 22 W while the temperature rise reaches 90° when the crystal is not cooled. However, the large face covered by the mirror becomes only functionalized for cooling and guiding the emitted beams. We lose the possibility to pump this functionalized face thus leading to a decrease of the potential pump power by 50%.

The invention aims to alleviate certain problems of the prior art. To this end, an object of the invention is a light emitting device comprising a solid parallelepiped luminescent crystal pumped by a plurality of light emitting diodes wherein one of the faces of the concentrator is in contact with a cooling medium adapted to remove at least a portion of a heat generated within said concentrator by the plurality of light-emitting diodes, an index nₑₓₜ>1 of the cooling medium being adapted to the index of the exit medium and the index of the concentrator to limit the loss in light extraction efficiency of the exit beam induced by the cooling medium. In the invention, the crystal can thus be cooled efficiently by an optical contact with a cooling medium of controlled index without no or minimal effect on the light extraction efficiency of the concentrator.

### SUMMARY OF THE INVENTION

To this end, an object of the invention is a light emitting device comprising:
a plurality of light emitting diodes configured to emit an incident light;
a solid luminescent light-concentrator of index n_{c} comprising two parallel faces, called first and second large faces, along an horizontal plane xy, and n∈ [symbol] >2 faces called side faces, at least one of the first and the second large face being illuminated by said incident light, said concentrator being configured to absorb said incident light and then emit a luminescent light, a portion of the luminescent light being guided by total internal reflection (L_{g}) in the concentrator and passes through a first so-called exit face of said concentrator in contact with an exit medium of index nₛ<n_{c}, and forms an exit beam,
a so-called cooling system comprising a cooling medium in contact with at least one of the faces of the concentrator, called cooled face, the cooling system being adapted to remove at least a portion of a heat generated within said concentrator by said plurality of light-emitting diodes, an index nₑₓₜ of the cooling medium being such that n_{c}>nₑₓₜ>1 and adapted to the index of the exit medium and the index of the concentrator to limit the loss in light extraction efficiency of the exit beam induced by the cooling medium.

In a preferred embodiment of the invention, the index of the cooling medium is such that the loss in light extraction efficiency of the exit beam is lower or equal to 15%.

In a preferred embodiment of the invention, the index of the cooling medium is such that

$${n}_{ext} \leq \frac{{n}_{s}}{tan ( {sin}^{- 1} ( \frac{{n}_{s}}{{n}_{c}} ) )} .$$

In a preferred embodiment of the invention, the cooling medium is in contact with at least 90% of said cooled face.

In a variant of the invention, the cooling medium is in contact with the first and the second large faces.

In an embodiment of the invention, the cooling system comprises a layer in a heat conducting material that conducts the heat to mechanical radiators, said layer forming the cooling medium.

In an embodiment of the invention the cooling medium is water.

In an embodiment of the invention the cooling system comprises a holder adapted to support the concentrator and the plurality of light emitting diodes, a channel connected to a water supply, the channel being adapted to transport said water, the holder comprising sealing elements adapted to ensure the sealing of the device.

In a preferred embodiment of the invention, the device comprises a mirror covering a face of the concentrator opposite to the exit face.

In an embodiment of the invention, the device comprises an additional solid luminescent light concentrator, said exit beam pumping the additional concentrator via a so called receiving face of the additional concentrator, in contact with the exit medium, wherein the additional concentrator is adapted to absorb the exit beam and then emit an additional luminescent radiation, wherein a portion of the additional luminescent radiation passes through a so-called additional exit face of the additional concentrator and forms an exit beam, wherein the additional exit face is in contact with an additional exit medium of index n's, wherein the index nₛ of the exit medium is adapted to the index of the additional concentrator and the index n′ₛ of the additional exit medium to achieve the highest extraction efficiency possible of the additional exit beam.

### BRIEF DESCRIPTION OF THE DRAWINGS

Other features, details and advantages of the invention will become apparent from the description made with reference to the annexed drawings, which are given as examples and which represent, respectively:

FIG. 1A, a light emitting module known in the prior art based on a concentrator crystal,

FIG. 1B, a planar representation of the escape cones L_{g}, and Lₒᵤₜ of the light emitting module of the prior art,

FIG. 2A, a light emission device according to the invention,

FIG. 2B a representation of the escape cones associated to the rays L_{g}, Lₛ, L_{out,1} and L_{out,2}, of the light emission device according to the invention,

FIG. 2C, a planar representation of the escape cones of the rays L_{g}, Lₛ, L_{out,1} and L_{out,2} of the device according to the second embodiment,

FIG. 2D, a planar representation of the escape cones of the rays L_{g}, Lₛ, L_{out,1} and L_{out,2} of the device according to the third embodiment,

FIG. 3A, a light emission device according to a variant of the invention,

FIG. 3B, a planar representation of the escape cones of the rays L_{g}, Lₛ, L_{out,1} and L_{out,2} of the device according to a variant of the invention,

FIG. 4, a planar representation of the escape cones of the rays L_{g}, Lₛ, L_{out,1} and L_{out,2} of the device according to the fourth embodiment,

FIG. 5, a planar representation of the escape cones of the rays L_{g}, Lₛ, L_{out,1} and L_{out,2} of the device according to the embodiment,

FIG. 6A, FIG. 6B, FIG. 6C, a perspective view, a profile view according to section A-B and profile view according to section C-D respectively, of a light emitting device according to another embodiment of the invention,

FIG. 7, a light emitting device according to another embodiment of the invention,

FIG. 8, a light emitting device according to another embodiment of the invention wherein the device comprises a cascade of two luminescent concentrators CL, CL′.

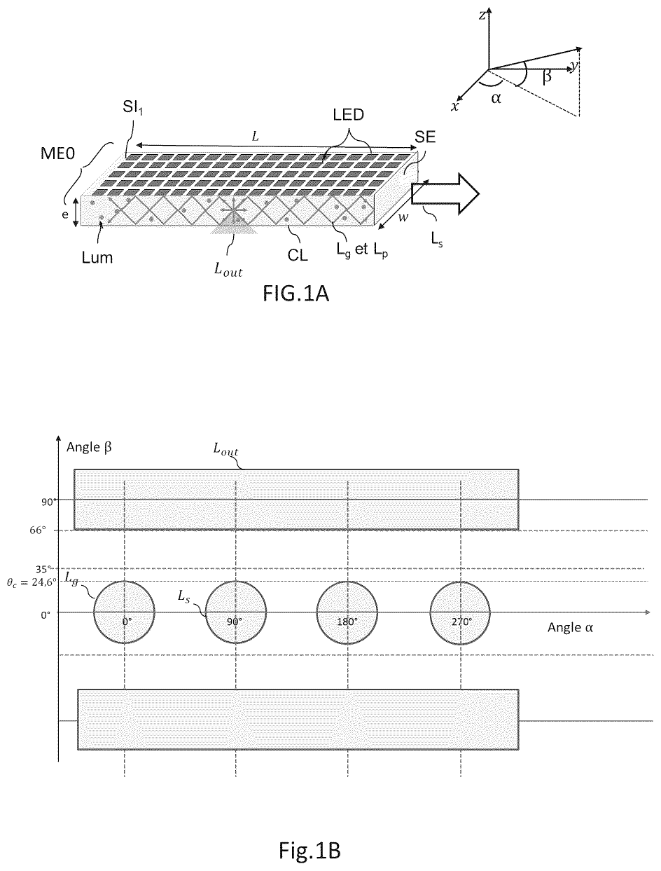

In the drawings, unless otherwise indicated, the elements are not to scale.

### DETAILED SPECIFICATION

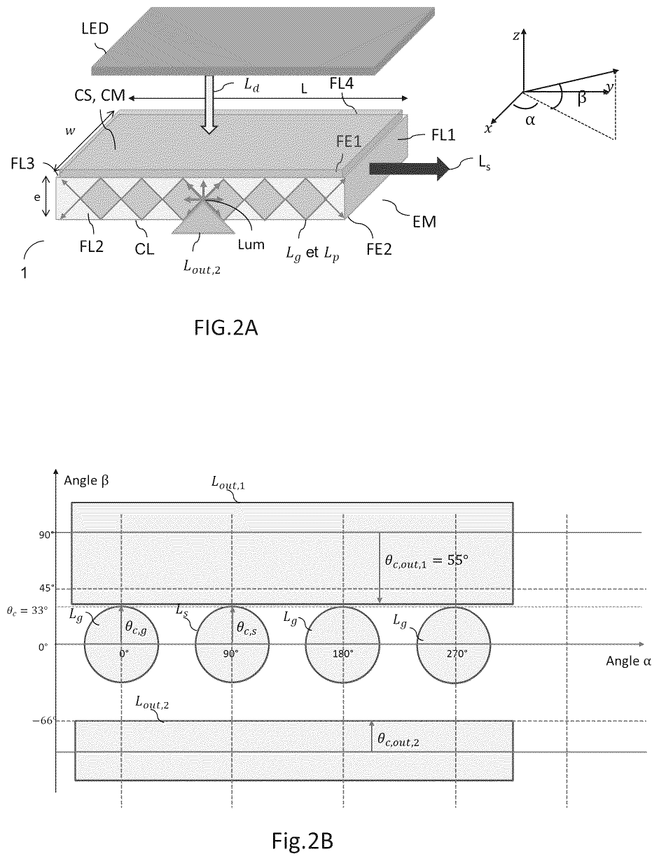

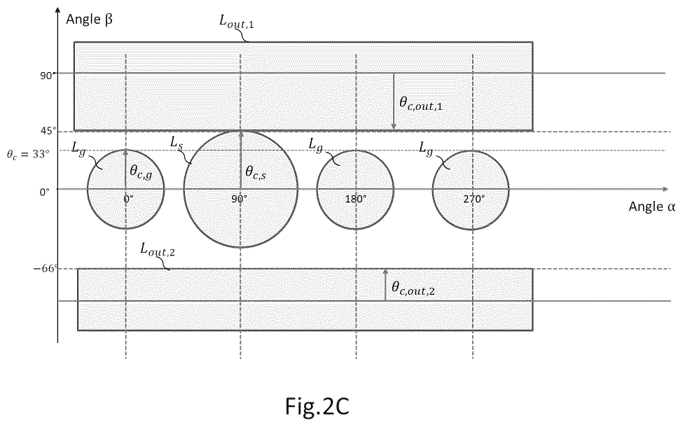

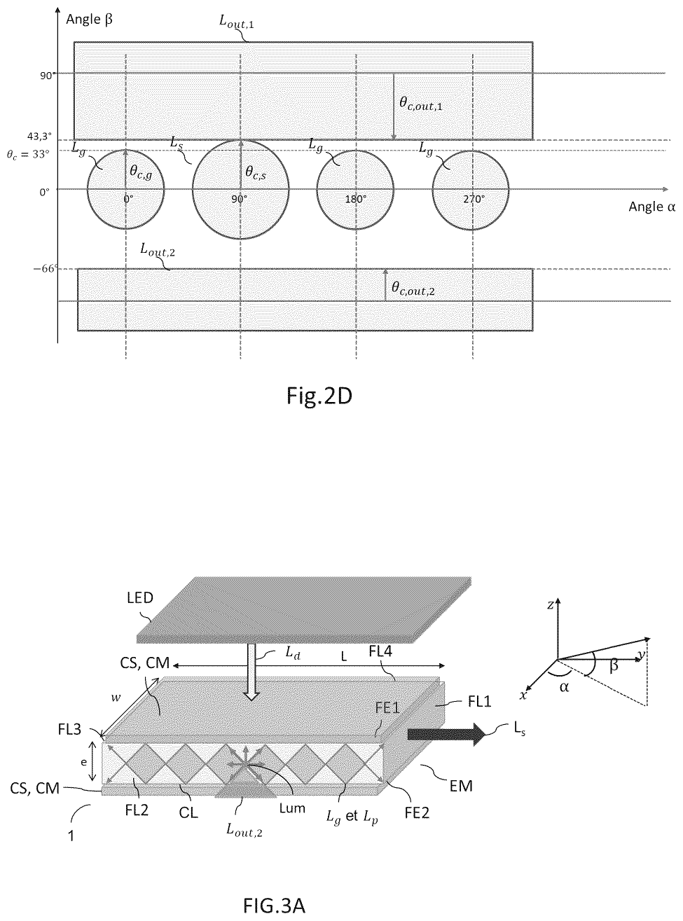

FIG. 2A illustrates a light emission device 1 according to the invention. The device 1 of the invention comprises a plurality of light emitting diodes LED configured to emit an incident light Ld.

To increase the luminance of the light emitting diodes LED, the device of the invention comprises a solid luminescent light-concentrator CL of index n_{c} comprising two parallel faces, called first and second large faces FE1, FE2, along an horizontal plane xy, and n∈ [symbol] >2 faces called side faces FL1, FL2, FL3, F4. Given as an illustrative example in FIG. 2A, the concentrator CL is a rectangular parallelepiped with a thickness e and has a first and a second large face FE1, FE2 of dimensions L×w in a horizontal plane xy.

The light emitting diodes LED pump the concentrator CL via at least one of the first and the second large face illuminated by the incident light Ld. The incident light Ld is absorbed by the luminophores Lum of the luminescent concentrator CL which are distributed throughout the volume of the crystal and which then emit a luminescent light LL inside the crystal.

According to one embodiment, the concentrator is a crystal, like Ce:YAG or Ce:LYSO. In another embodiment, the light concentrator is not a crystal but another material, like glass or PMMA doped by luminophores.

As known to one skilled in the art, a portion, called trapped portion Lp, of said luminescent light is trapped by total internal reflection in said concentrator. As previously stated, the ratio of trapped and untrapped rays is fixed by the index of the concentrator and the index of the ambient medium, by the Snell-Descartes law. Trapped rays are noted Lp and can never leave the concentrator due to the TIR on the different faces of the concentrator. The untrapped rays are the rays that eventually leave the concentrator. They can be separated into two sub-categories: guided rays Lg, which are guided by TIR on the large faces or side faces and emerge on one of the faces of the concentrator; and unguided rays L_{out,1} and L_{out,2} which emerge directly from the face FE1 and FE2 of the concentrator respectively, without being reflected on the faces.

A portion Lₛ of the guided rays L_{g} passes through a first so-called exit face FL1 of the concentrator in contact with an exit medium EM of index nₛ<n_{c}, and forms an exit beam Lₛ. Given as an illustrative example, in FIG. 2A, the exit face FL1 has dimensions e×w. In another embodiment, the exit face is formed by another side face, for example side face FL2, with dimension L×w.

According to one embodiment of the invention, the exit medium is air (see FIG. 2B for example). In another embodiment, to increase the light extraction efficiency of the exit beam, the exit medium has an index nₛ>1 (see FIG. 2C for example).

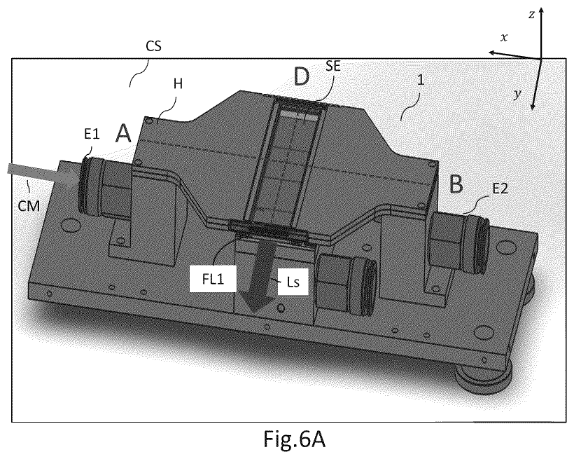

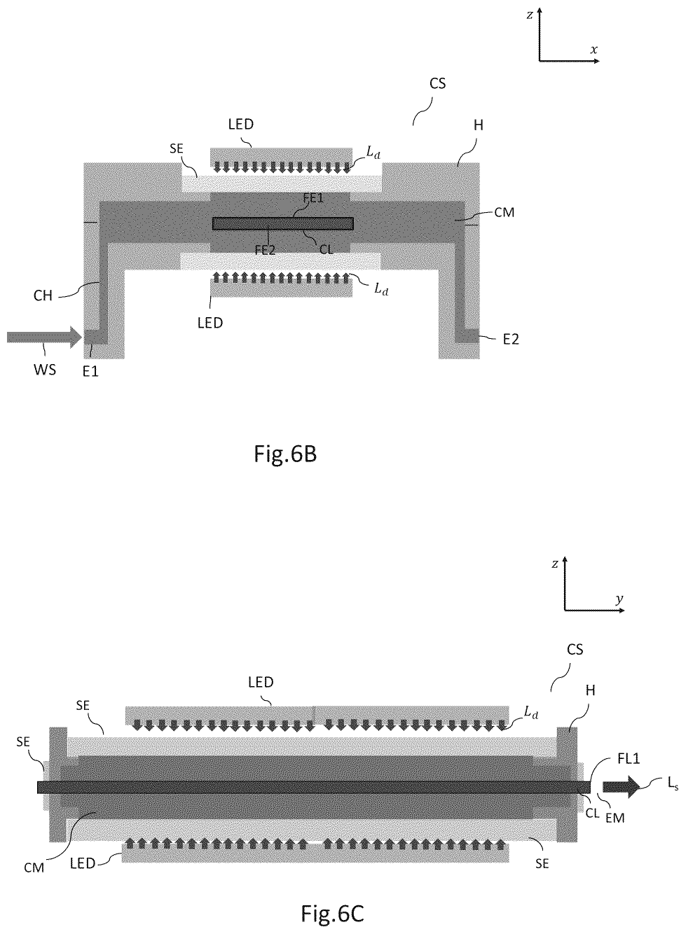

The device of the invention comprises a so-called cooling system CS comprising a cooling medium CM in contact with at least one of the faces of the concentrator (called hereinafter “cooled face”). The cooling system is adapted to remove at least a portion of the heat generated within the concentrator CL by the plurality of light-emitting diodes LED. The index nₑₓₜ of the cooling medium is such that n_{c}>nₑₓₜ>1 to allow a thermal conductivity higher than air. Unlike light emitting devices of the prior art, the cooling medium is in uniform contact with the majority of the surface of the cooled face FE1. More precisely, the cooling medium is in contact with more than 90% of the cooled face. This allows for a much more efficient cooling of the pump power compared to prior art configurations using only a single point of contact with the cooled face. Given as an illustrative example, in FIG. 2A, the only cooled face is large face FE1. In another embodiment of the invention, to increase the heat removed by the cooling system, more faces of the concentrator CL are in contact with the cooling medium, for example FE1 and FE2 (see for example FIG. 3A), or FE1, FE2, FL2 and FL4 (see for example FIGS. 6A-6C). Thus, more LEDs and more pump power can be used.

The cooling system CS can remove the heat while preserving the total internal reflection of the light Lₛ guided in the concentrator and passing through the exit face FE1. More precisely, the index nₑₓₜ of the cooling medium CM is adapted to the index of the exit medium nₛ and the index of the concentrator n_{c} to limit the loss in light extraction efficiency of the exit beam Lₛ induced by the cooling medium CM. Indeed, as previously stated, the total internal reflection on the guiding faces of the concentrator CL is very sensitive to contact with materials of higher index than air. Thus, if nₑₓₜ is not carefully chosen, the presence of the cooling medium in contact with the cooled face FE1 can induce an important light leakage from faces other than the exit face reducing the light extraction efficiency of the exit beam Lₛ.

Preferably, the index of the cooling medium is such that the cooling medium induces no loss in the light extraction efficiency of the exit beam (see eg: FIGS. 2B to 4).

In the embodiment illustrated in FIG. 2A, the face of the concentrator pumped by the diodes LED is the same as the face in contact with the cooling medium, FE1. Therefore, in this embodiment, it is necessary that the cooling medium CM is transparent to the incident light emitted by the LEDs. More generally, when the cooling medium covers a face that is pumped by the LEDs, the cooling is transparent to the light emitted by the LEDs.

In order to better understand the influence of the cooling medium on the extraction efficiency, FIG. 2B illustrates a representation of the escape cones associated to the rays L_{g}, Lₛ, L_{out,1} and L_{out,2} using angular coordinates (α, β) in the xyz frame of reference of FIG. 2A. The lighter area in between the cones corresponds to the trapped rays Lp.

As an example, the representation of FIG. 2B is given with respect to the concentrator of the invention illustrated in FIG. 2A, with a cooling medium of index nₑₓₜ=1.5 and an exit medium nₛ=1 (air). Thus, the faces other than the cooled face are in ambient air. We call this embodiment of the invention, first embodiment M1. As an example, the concentrator CL is a Ce:YAG crystal of index n_{c}=1.83.

The escape cones of FIG. 2B denoted 0°, 180° and 270° corresponds to the range of angles of guided rays L_{g} that exits the sides faces FL2, FL4 and FL3 respectively. We call θ_{c,g} the critical angle of these escape cones. The escape cones associated to the rays Lₛ forming the exit beam is denoted 90° in FIG. 2B. We call θ_{c,s} the critical angle of this escape cone. Given the indexes and the geometry of this embodiment M1, the critical angle of the TIR on the faces FL1, FL2, FL3, FL4 and FE2 of the concentrator in contact with air is

$${θ}_{c , g} = {θ}_{c , s} = {sin}^{- 1} ( \frac{{n}_{s}}{{n}_{c}} ) = {sin}^{- 1} ( \frac{1}{1.83} ) = 33 ° .$$

Rays propagating inside the concentrator with an angle higher or equal than that critical angle, with respect to the normal of those faces, are trapped within the concentrator CL. As can be seen in FIG. 2B, the critical angle

$${θ}_{c , out 1} = {sin}^{- 1} ( \frac{{n}_{ext}}{{n}_{c}} ) = 55 °$$

of the escape cone of the rays L_{out,1} associated to the cooled face FE1 is greater than the critical angle θ_{c,out2}=θ_{c,g}=33° of the escape cone of the rays L_{out,2} associated to the large face FE2. This is because the cooling medium CM in contact with the cooled face FE1 has an index nₑₓₜ such that n_{c}>nₑₓₜ>1 and thus greater than the index of air which is the medium in contact with face FE2.

To ensure that the cooling medium CM does not induce a loss in light extraction efficiency of the exit beam Lₛ, it is necessary that there is no overlap between the range of angles of the rays L_{out,1} and the range of angles of the rays Lₛ. In the configuration illustrated in FIG. 2B, given the Snell-Descartes law, there will be no overlap, as long as:

$${n}_{ext} \leq {n}_{c} . sin ( 90 ° - {θ}_{c , s} ) . \qquad ( EQ 0 )$$

In embodiment M1, given θ_{c,s}=33° and n_{c}=1.83, this means that there will be no overlap as long as nₑₓₜ≤1.53. As nₑₓₜ=1.5 in the embodiment M1, there is no overlap between the range of angles of the rays L_{out,1} and the range of angles of the rays Lₛ.

EQ0 implies that it is possible to use water as a cooling medium without inducing a loss in light extraction efficiency of the exit beam Lₛ. Therefore, in an embodiment of the invention, the cooling medium is water (nₑₓₜ=1.333), the concentrator is in Ce:YAG and all the faces other than the cooled face FE1 are in contact with air. In this embodiment, the medium CM does not induce a loss in the light extraction efficiency of the exit beam Lₛ because nₑₓₜ≤1.53. For this embodiment as well, the share of luminescent light exiting the exit face FL1 (ie: the light extraction efficiency) is 8% of the total luminescent light emitted by the concentrator.

The use of water to cool the concentrator CL is advantageous because this type of cooling can be shared with the LEDs. Indeed, as the efficiency of LEDs is about 30%, it is necessary to evacuate a large part of the power (at the kW level if thousands of LEDs are used). Therefore, in a preferred embodiment of the invention, the number of light emitting diodes LED pumping the concentrator CL comprised in the device 1 is greater or equal to a thousand, the cooling medium is water, and the cooling system is adapted to cool both the concentrator CL and the LED with said water.

The device of the invention can therefore use a cooling medium with higher thermal conductivity than air (like water) to remove efficiently the heat generated in the concentrator CL by the LEDs, without inducing a loss in the light extraction efficiency of the exit beam Lₛ.

In the embodiment illustrated in FIG. 2A, only the large face FE1 is pumped. In another embodiment, to achieve a higher pump power and therefore a higher power of the exit beam Lₛ, both of the large faces FE1 and FE2 are pumped by LEDs.

To achieve a higher light extraction efficiency of the exit beam, in a second embodiment M2 of the invention, the exit medium has an index nₛ higher than air (nₛ>1) and equal to the index nₑₓₜ of the cooling medium (nₛ=nₑₓₜ). For example, the exit medium can be a glue, or water. FIG. 2C which shows a planar representation of the escape cones of the rays L_{g}, Lₛ, L_{out,1} and L_{out,2} of the second embodiment M2, using the same angular coordinates (α, β) as FIG. 2B. Like in the representation of FIG. 2B, as an example, the representation of FIG. 2C is given with respect to the concentrator of the invention illustrated in FIG. 2A, with a Ce:YAG crystal of index n_{c}=1.83. The faces other than the cooled face and the exit face are in air. To achieve the highest lossless extraction efficiency of the Lₛ beam possible given an index n_{c}, it is necessary that

$${n}_{s} = {n}_{ext} = {n}_{c} . sin ( 45 ° ) = \frac{{n}_{c}}{\sqrt{2}} = 1.29 .$$

By lossless, it is meant that there is no light leakage of rays Lₛ through the cooled face or any face other than the exit face before passing through the exit face FL1. That is because θ_{c,s}=θ_{c,out1}=45° and thus, there is no overlap between the range of angles of the rays L_{out,1} exiting the cooled face FE1 and the rays Lₛ exiting the exit face FL1. Using an exit medium with the same index nₛ as the cooling medium, we have increased the light extraction efficiency of the exit beam from 8% in the embodiment M2 to 14.5% in the embodiment M2, while maintaining a lossless extraction.

In a third embodiment M3 of the invention, the exit medium has an index nₛ different to the index nₑₓₜ of the cooling medium (nₛ≠nₑₓₜ). This can be interesting to achieve a higher light extraction efficiency of the exit beam Lₛ than in the embodiment M2 in which nₛ=nₑₓₜ, by using nₛ>nₑₓₜ. Or it can be advantageous to use a specific cooling medium (eg: water) no suited for the exit medium. For a given index nₛ of exit medium, to ensure a lossless extraction efficiency, it is necessary that:

$${θ}_{c , s} + {θ}_{c , out 1} \leq 90 °$$

Which gives:

$${sin}^{- 1} ( {n}_{s} / {n}_{c} ) + {sin}^{- 1} ( {n}_{ext} / {n}_{c} ) \leq 90 °$$

Which gives the following condition on the index of the cooling medium:

$${n}_{ext} \leq {n}_{c} . cos ( {sin}^{- 1} ( \frac{{n}_{s}}{{n}_{c}} ) ) , equivalent to \qquad ( EQ 1 )$$

$${n}_{ext} \leq \frac{{n}_{s}}{tan ( {sin}^{- 1} ( \frac{{n}_{s}}{{n}_{c}} ) )} \qquad ( EQ 1 ’ )$$

In this embodiment M3, a higher extraction efficiency of the Lₛ beam is achievable than the embodiment M1 that uses air as an exit medium, while still achieving a lossless extraction efficiency of the Lₛ beam. In this embodiment, a cooling medium with higher thermal conductivity than air can be used to remove the heat generated in the concentrator CL by the LEDs, while achieving a high and lossless light extraction efficiency. FIG. 2D shows a planar representation of the escape cones of the rays L_{g}, Lₛ, L_{out,1} and L_{out,2} of this embodiment, using the same angular coordinates (α, β) as FIG. 2B. In the illustration of FIG. 3B given as an example, the cooling medium is water (nₑₓₜ=1.33, θ_{c,out,1}=46,6° and the concentrator CL is a Ce:YAG crystal of index n_{c}=1.83. The exit medium has a refractive index of nₛ=1.22. The faces other than the cooled face and the exit face are in air.

To achieve a better removal of the heat generated in the concentrator CL, in a variant of the embodiment illustrated in FIG. 3A, the second large face FE2 is also in contact with the cooling medium CM. Thus, more LEDs and more pump power can be used, and an exit beam with more power can be achieved. FIG. 3B shows a planar representation of the escape cones of the rays L_{g}, Lₛ, L_{out,1} and L_{out,2} of this variant, using the same angular coordinates (α, β) as FIG. 2B. In the illustration of FIG. 3B given as an example, nₛ=nₑₓₜ=1.29 and the concentrator CL is a Ce:YAG crystal of index n_{c}=1.83. The faces other than the cooled face and the exit face are in air. Because the second large face FE2 is also in contact with the cooling medium CM, one can see from FIG. 3B that the critical angle θ_{c,out1}=33° of the escape cone of the rays L_{out,1} associated to the cooled face FE1 is equal to the critical angle θ_{c,out2}=33° of the escape cone of the rays L_{out,2} associated to the other cooled face FE2. Because the index of the cooling medium was chosen appropriately with respect to the index of the exit medium and the index of the concentrator

$$( {n}_{s} = {n}_{ext} = {n}_{c} . sin ( 45 ° ) = \frac{{n}_{c}}{\sqrt{2}} = 1.29 ) ,$$

there is no overlap between the range of angles of the rays exiting the cooled faces FE1 and FE2 and the range of angles of the rays Lₛ. Thus, the light extraction efficiency of the exit beam Lₛ is lossless.

To increase the extraction efficiency of the Lₛ beam, in an embodiment of the invention, compatible with all the previously mentioned embodiments of the invention, the device comprises a mirror covering the face of the concentrator opposite to the exit face FL1. Thus, all the rays forming the escape cone of the face FL3 are reflected in the concentrator CL and then exit through the exit face and contribute to the power of the exit beam Lₛ instead of exiting through FL3. As an example, in the embodiment of FIG. 2B, a mirror covering the face of the concentrator opposite to the exit face FL1 doubles the extraction efficiency of the Lₛ beam from 8% to 2×8%=16%, assuming the mirror has reflection coefficient of 1 and not taking into account propagation losses due to absorption inside the concentrator CL.

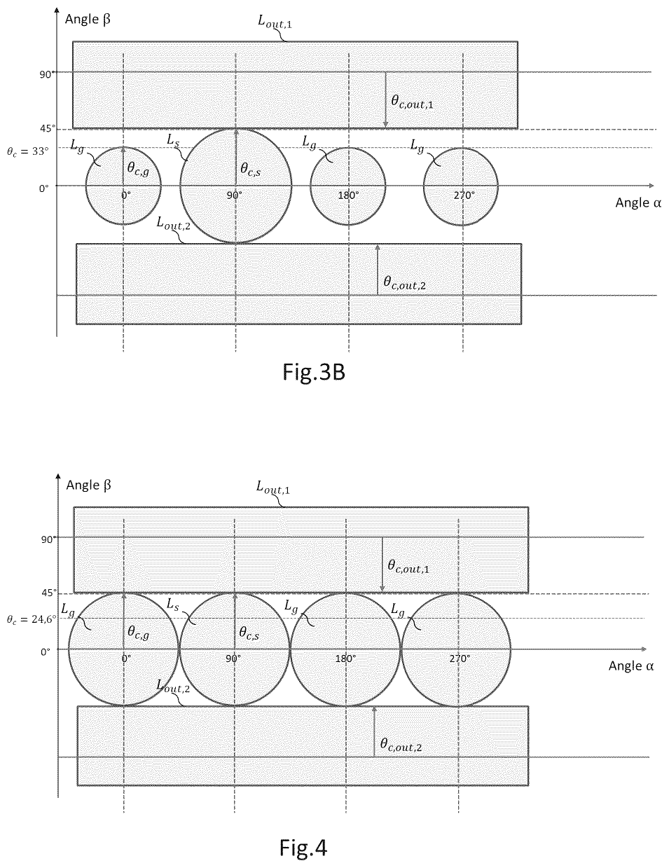

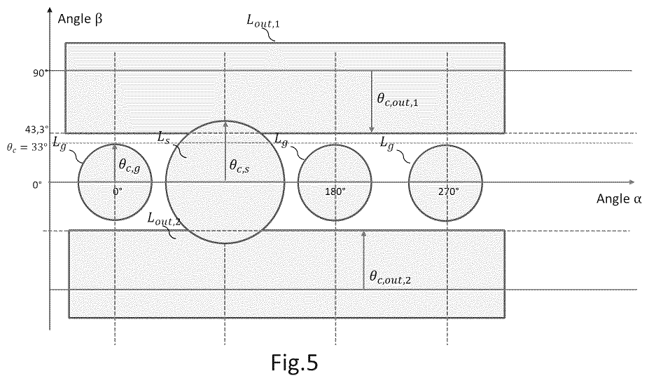

To achieve the best heat removal possible, in a fourth embodiment M4 of the invention, all the faces of the concentrator CL including the exit face FL1 are in contact with the cooling medium. This implies that nₛ=nₑₓₜ. FIG. 4 shows a planar representation of the escape cones of the rays L_{g}, Lₛ, L_{out,1} and L_{out,2} of this fourth embodiment M4, using the same angular coordinates (α, β) as FIG. 2B. In the illustration of FIG. 4, given as an example

$${n}_{s} = {n}_{ext} = \frac{{n}_{c}}{√ 2} = 1.29$$

and the concentrator CL is a Ce:YAG crystal of index n_{c}=1.83. As seen in FIG. 4, those indexes imply that the critical angle associated with every escape cones of the rays L_{g}, Lₛ, L_{out,1} and L_{out,2} is equal to

$${sin}^{- 1} ( \frac{1.29}{1.83} ) = 45 ° .$$

The highest value of nₑₓₜ with respect to n_{c} to ensure the highest lossless light extraction efficiency of the Lₛ beam possible is calculated from EQ1, assuming nₛ=nₑₓₜ. This value is given by

$${n}_{ext} = \frac{{n}_{c}}{\sqrt{2}} .$$

It is understood from the various embodiments, that the index of the exit medium nₛ is actually adapted to the index of the concentrator, and to the index of the ambient medium in contact with the other faces (ie: faces other than the exit face an the cooled face(s)) to limit the loss in light extraction efficiency of the exit beam. Indeed, if the index of the ambient medium in contact with the other faces is different to the index of the exit medium, it is possible to have θ_{c,s}+θ_{c,g}>90° and thus have an overlap between the space cones of the other faces and the escape cone of the exit face. Thus, is a preferred embodiment, the index of the exit medium nₛ is such that θ_{c,s}+θ_{c,g}≤90°.

According to fifth embodiment M5 of the invention, the index of the cooling medium CM is such that the loss in light extraction efficiency of the exit beam induced by the cooling medium CM is lower or equal to 15%. FIG. 5 shows a planar representation of the escape cones of the rays L_{g}, Lₛ, L_{out,1} and L_{out,2} of this embodiment M5, using the same angular coordinates (α, β) as FIG. 2B. Given as an example, the device is identical to the embodiment of FIG. 3A, with the cooling medium being water, with the exit medium EM having an index nₛ=1.5 and with a Ce:YAG crystal. All the other faces, other than the exit face and the cooled faces, are in air. Given the indexes and the structure of the device, the critical angles associated with the large faces (here both cooled faces) FE1, FE2 are

$${θ}_{c , out , 1} = {θ}_{c , out , 2} = {sin}^{- 1} ( \frac{1.333}{1.83} ) = 46.6 ° .$$

The escape cones associated with the faces FL2, FL3 and FL4 have a critical angle θ_{c,g}=33°. Because the exit medium has an index nₛ=1.5, the critical angle of the escape cone of the Lₛ rays is

$${θ}_{c , s} = {sin}^{- 1} ( \frac{1.5}{1.83} ) = 55.1 ° .$$

Thus, θ_{c,s}+θ_{c,out,1}=θ_{c,s}+θ_{c,out,2}>90° and there is an overlap between the range of angles of the escape cones of rays L_{out,1}/L_{out,2} and the range of angles of the escape cone of rays Lₛ. This means that rays of the luminescent light within this range of angles will leak out the concentrator through the cooled faces FE1 and FE2 instead of passing through the exit face FL1. This leads to a decrease of the light extraction efficiency of the exit beam Lₛ. With the parameters used for the illustration of FIG. 5, in the fifth embodiment M5, the overlap induces a loss of 11,5% in light extraction efficiency.

FIG. 6A, 6B, 6C illustrate a perspective view, a profile view according to section A-B and profile view according to section C-D respectively, of a light emitting device according to another embodiment of the invention. In this embodiment, the cooling system comprises a holder H adapted to support the concentrator CL and the plurality of light emitting diodes LED. As an example, the holder can be made of metal like aluminum or copper. The holder comprises a channel CH adapted to be connected to a water supply WS (not represented in FIG. 6A but visible in FIG. 6B) via one extremity E1. The water flowing in channel CH forms the cooling medium. More precisely, the channel is adapted to transport the water flowing from the water supply from the extremity E1 to the extremity E2 so that the water is in contact with the totality of side face FL2 and FL4 and is in contact with more than 90% of the surface of the faces FE1 and FE2 illuminated by the incident light La. The holder comprises sealing elements SE adapted to ensure the sealing of the device 1. The sealing elements in the direct path of the incident light La are transparent to said incident light. Because water flowing in the channel CH is in contact with the majority of the surface of the concentrator CL, the embodiment of FIG. 6A is suitable to remove heat in the concentrator generated by pump power of high value (eg: for several thousands of light emitting diodes). For a concentrator with dimensions 105 mm×22 mm×1 mm, with a water flux of 4 L/min and with a temperature difference of 10° C. between the water and the concentrator, the light emitting device of FIGS. 6A to 6C, via the cooling medium, can extract up to 185.4 W of thermal power. This calculation was made using finite element analysis. As a comparison, if the only cooled faces are the faces FE1, FE2, 177.3 W of thermal power can be extracted. This shows that the large faces are much more efficient in cooling the concentrator. If the cooling medium was air in the device of FIGS. 6A to 6C, only 12.3 W of thermal power could be extracted.

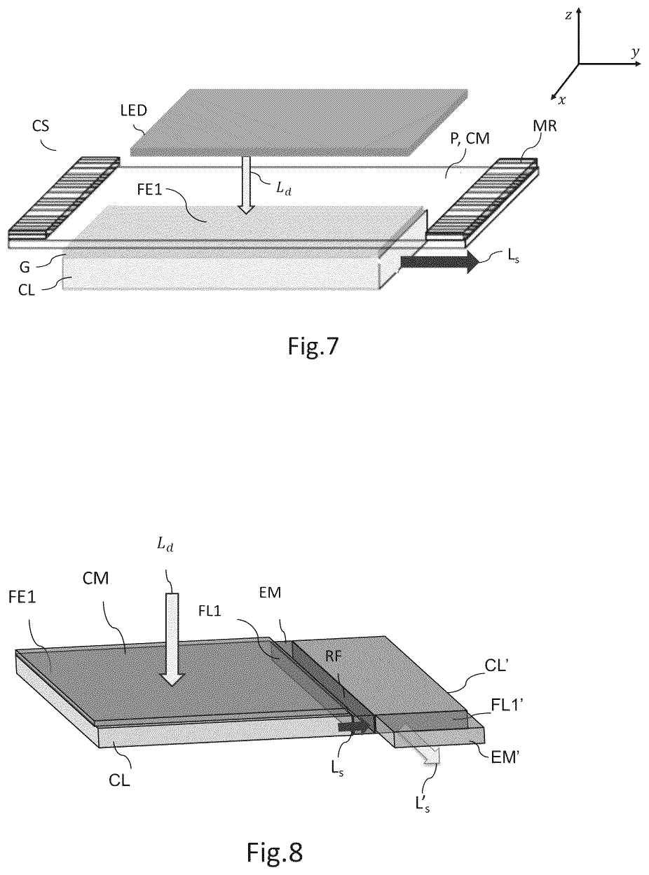

FIG. 7 illustrates a light emitting device according to another embodiment of the invention. In this embodiment, the cooling system comprises a layer P in a heat conducting material that conducts the heat to mechanical radiators MR. The layer P forms the cooling medium CM. In the embodiment illustrated in FIG. 7, the face FE1 of the concentrator pumped by the diodes LED is the same as the face in contact with the layer P. Therefore, in this embodiment, it is necessary that the layer is transparent to the incident light emitted by the LEDs. As an example, the layer is in CaF2 or sapphire. Furthermore, preferably, the mechanical radiators MR are located outside the path of the incident light in order not to block said incident light. In the embodiment of FIG. 7, the device 1 comprises a thin sub-layer G typically optical glue, that binds the layer P to the cooled face FE1. This sub-layer G is optional.

The embodiment of FIG. 7 is suitable to remove heat in the concentrator generated by pump power of moderate value (eg: for several hundreds of light emitting diodes).

FIG. 8 illustrates a light emitting device according to another embodiment of the invention, wherein the device comprises a cascade of two luminescent concentrators CL, CL′. In this embodiment, as an illustrative example, the only cooled face of the concentrator CL is the large face FE1. The exit beam Lₛ passes through the exit face FL1 of the concentrator CL, in contact with an exit medium EM, before pumping the additional concentrator CL′ via a so called receiving face RF also in contact with the exit medium EM. The additional concentrator is adapted to absorb the rays of the exit beam Lₛ and then emit an additional luminescent radiation. As explained previously, a portion of the additional luminescent radiation passes through a so-called additional exit face FL1′ of the additional concentrator and forms an exit beam L′ₛ. The additional exit face FL1′ is in contact with an additional exit medium EM′ of index n's. As an example, all the other faces other than the cooled face FE1, the exit face FL1, the additional exit face FL1′ and the receiving face RF are in air. In the embodiment of FIG. 8, the exit medium is adapted to increase the extraction efficiency of the exit beam Lₛ but also to maintain a mechanical contact between the two concentrators CL and CL′.

Like in all the previous embodiments, in the embodiment of FIG. 8, the index nₑₓₜ of the cooling medium is adapted to the index of the exit medium and to the index of the concentrator CL to limit the loss in light extraction efficiency of the exit beam Lₛ induced by the cooling medium. To achieve the highest extraction efficiency possible of the additional exit beam L′ₛ, the index nₛ of the exit medium EM is also adapted to the index of the additional concentrator CL′ and the index n′ₛ of the additional exit medium. More precisely, the index nₛ of the exit medium is such that there is no overlap between the escape cone of the additional luminescent light associated to the face FL1′ and the escape cone of the additional luminescent light associated to the face RF. Thus, an efficient cascade of luminescent light concentrators is achieved in the embodiment of FIG. 8 to increase the light extraction efficiency of the additional exit beam L′ₛ, in a variant of the embodiment of FIG. 8, mirrors cover the side faces of the additional concentrator other than the additional exit face FL1′.

1-10. (canceled)

11. A light emitting device comprising:
a plurality of light emitting diodes configured to emit an incident light (Ld);
a solid luminescent light-concentrator of index n_{c} comprising two parallel faces, called first and second large faces, along an horizontal plane xy, and n∈ [symbol] >2 faces called side faces, at least one of the first and the second large face being illuminated by said incident light, said concentrator being configured to absorb said incident light and then emit a luminescent light, a portion of the luminescent light being guided by total internal reflection in the concentrator and passes through a first so-called exit face of said concentrator in contact with an exit medium of index nₛ<n_{c}, and forms an exit beam;
a so-called cooling system comprising a cooling medium in contact with at least one of the faces of the concentrator, called cooled face, the cooling system being adapted to remove at least a portion of a heat generated within said concentrator by said plurality of light-emitting diodes, an index nₑₓₜ of the cooling medium being such that n_{c}>nₑₓₜ>1 and such that nₛ≠nₑₓₜ, and adapted to the index of the exit medium and the index of the concentrator to limit the loss in light extraction efficiency of the exit beam induced by the cooling medium.

12. The device according to claim 11, wherein the index of the cooling medium is such that the loss in light extraction efficiency of the exit beam is lower or equal to 15%.

13. The device according to claim 11, wherein the index of the cooling medium is such that
$${n}_{ext} \leq \frac{{n}_{s}}{tan ( {sin}^{- 1} ( \frac{{n}_{s}}{{n}_{c}} ) )} .$$

14. The device according to claim 11, wherein the cooling medium is in contact with at least 90% of said cooled face.

15. The device according to claim 11, wherein the cooling medium is in contact with the first and the second large faces.

16. The device according to claim 11, wherein the cooling system comprises a layer in a heat conducting material that conducts the heat to mechanical radiators, said layer forming the cooling medium.

17. The device according to claim 11, wherein the cooling medium is water.

18. The device according to claim 17, wherein the cooling system comprises a holder adapted to support the concentrator and the plurality of light emitting diodes, a channel connected to a water supply, the channel being adapted to transport said water, the holder comprising sealing elements adapted to ensure the sealing of the device.

19. The device according to claim 11, comprising a mirror covering a face of the concentrator opposite to the exit face.

20. The device according to claim 11, comprising an additional solid luminescent light concentrator, said exit beam pumping the additional concentrator via a so called receiving face of the additional concentrator, in contact with the exit medium, wherein the additional concentrator is adapted to absorb the exit beam and then emit an additional luminescent radiation, wherein a portion of the additional luminescent radiation passes through a so-called additional exit face of the additional concentrator and forms an exit beam wherein the additional exit face is in contact with an additional exit medium of index n′ₛ, wherein the index n′ₛ of the exit medium is adapted to the index of the additional concentrator and the index n′ₛ of the additional exit medium to achieve the highest extraction efficiency possible of the additional exit beam.
